(19) United States
(12) Patent Application Publication
(10) Pub. No.: US 2024/0255546 A1
(43) Pub. Date: Aug. 1, 2024

(54) DIAGNOSTIC INSTRUMENT

(71) Applicant: Snap-on Incorporated, Kenosha, WI (US)

(72) Inventors: Joshua C. Covington, San Juan Bautista, CA (US); Kahlil H. Cacabelos, San Jose, CA (US); James A. Panko, Wonder Lake, IL (US); Yosuf M. Taraki, Skokie, IL (US)

(21) Appl. No.: 18/160,892

(22) Filed: Jan. 27, 2023

(51) Int. Cl. G01R 13/02

(52) U.S. Cl. CPC G01R 13/02

(57) ABSTRACT

An instrument includes an input port, a display, one or more processors, and a computer readable medium storing instructions that, when executed by the one or more processors, cause the instrument to perform functions. The functions include generating a first dataset indicating voltages of a signal detected at the input port over a time period and displaying the first dataset graphically on the display. The functions also include generating a second dataset indicating values of a derived characteristic of the signal over the time period and displaying the second dataset graphically on the display.

### BACKGROUND

Digital oscilloscopes and graphing multi-meters are similar instruments with different functions. The main function of a digital oscilloscope is to graphically display a voltage or current signal as a function of time. On the other hand, a graphing multi-meter is generally used to calculate and graphically display a numeric characteristic of a voltage or current signal over time. Thus, the graphing multi-meter is useful for identifying transient anomalies in the derived characteristic but generally cannot graphically display the signal to which the anomaly pertains. In a similar vein, a transient anomaly in the signal is difficult to identify with an oscilloscope.

Some instruments include a digital oscilloscope mode as well as a graphing multi-meter mode. If a user notices an anomaly while in graphing multi-meter mode, the user may wish to see the voltage signal that gave rise to anomaly. In this instance, the user can switch to oscilloscope mode, but if the anomaly is intermittent, it may not be possible to capture in oscilloscope mode.

### SUMMARY

A first example is an instrument comprising: an input port; a display; one or more processors; and a computer readable medium storing instructions that, when executed by the one or more processors, cause the instrument to perform functions comprising: generating a first dataset indicating voltages of a signal detected at the input port over a time period; displaying the first dataset graphically on the display; generating a second dataset indicating values of a derived characteristic of the signal over the time period; and displaying the second dataset graphically on the display.

A second example is a non-transitory computer readable medium storing instructions that, when executed by an instrument, cause the instrument to perform functions comprising: generating a first dataset indicating voltages of a signal detected at an input port over a time period; displaying the first dataset graphically on a display; generating a second dataset indicating values of a derived characteristic of the signal over the time period; and displaying the second dataset graphically on the display.

A third example is a method comprising: generating a first dataset indicating voltages of a signal detected at an input port over a time period; displaying the first dataset graphically on a display; generating a second dataset indicating values of a derived characteristic of the signal over the time period; and displaying the second dataset graphically on the display.

A fourth example is a method comprising: generating a dataset indicating voltages of a signal detected at an input port; displaying, with a first time resolution, the dataset graphically within a first area of a display; determining that an anomaly exists within the dataset; and displaying, with a second time resolution that is greater than the first time resolution, a subset of the dataset that includes the anomaly within a second area of the display.

A fifth example is a non-transitory computer readable medium storing instructions that, when executed by an instrument, cause the instrument to perform the method of the fourth example.

A sixth example is an instrument comprising: an input port; a display; one or more processors; and a computer readable medium storing instructions that, when executed by the one or more processors, cause the instrument to perform the method of the fourth example.

When the term “substantially” or “about” is used herein, it is meant that the recited characteristic, parameter, or value need not be achieved exactly, but that deviations or variations, including, for example, tolerances, measurement error, measurement accuracy limitations, and other factors known to those of skill in the art may occur in amounts that do not preclude the effect the characteristic was intended to provide. In some examples disclosed herein, “substantially” or “about” means within +/−0-5% of the recited value.

These, as well as other aspects, advantages, and alternatives will become apparent to those of ordinary skill in the art by reading the following detailed description, with reference where appropriate to the accompanying drawings. Further, it should be understood that this summary and other descriptions and figures provided herein are intended to illustrate the invention by way of example only and, as such, that numerous variations are possible.

### BRIEF DESCRIPTION OF THE DRAWINGS

FIG. 1 is a block diagram of an instrument, according to an example embodiment.

FIG. 2 shows a display of an instrument, according to an example embodiment.

FIG. 3 shows a display of an instrument, according to an example embodiment.

FIG. 4 shows a display of an instrument, according to an example embodiment.

FIG. 5 shows a display of an instrument, according to an example embodiment.

FIG. 6 shows a display of an instrument, according to an example embodiment.

FIG. 7 shows a display of an instrument, according to an example embodiment.

FIG. 8 shows a display of an instrument, according to an example embodiment.

FIG. 9 shows a display of an instrument, according to an example embodiment.

FIG. 10 shows a display of an instrument, according to an example embodiment.

FIG. 11 shows a display of an instrument, according to an example embodiment.

FIG. 12 shows a display of an instrument, according to an example embodiment.

FIG. 13 is a block diagram of a method, according to an example embodiment.

FIG. 14 is a block diagram of a method, according to an example embodiment.

### DETAILED DESCRIPTION

Within examples, an instrument includes an input port, a display, one or more processors, and a computer readable medium storing instructions that, when executed by the one or more processors, cause the instrument to perform functions. The functions include generating a first dataset indicating voltages of a signal detected at the input port over a time period and displaying the first dataset graphically on the display. The functions also include generating a second dataset indicating values of a derived characteristic of the signal over the time period and displaying the second dataset graphically on the display.

For example, the instrument can be used to monitor and graphically display a voltage signal in a first area of the display and calculate and graphically display a frequency, a duty cycle, or a pulse width of the signal in a second area of the display. Typically, the first area of the display will be refreshed at a higher frequency than the second area of the display. Thus, a user may be able to visually identify an anomaly of the derived characteristic of the signal in the second area of the display and operate the instrument to display the portion of the signal that produced the anomaly in the first area.

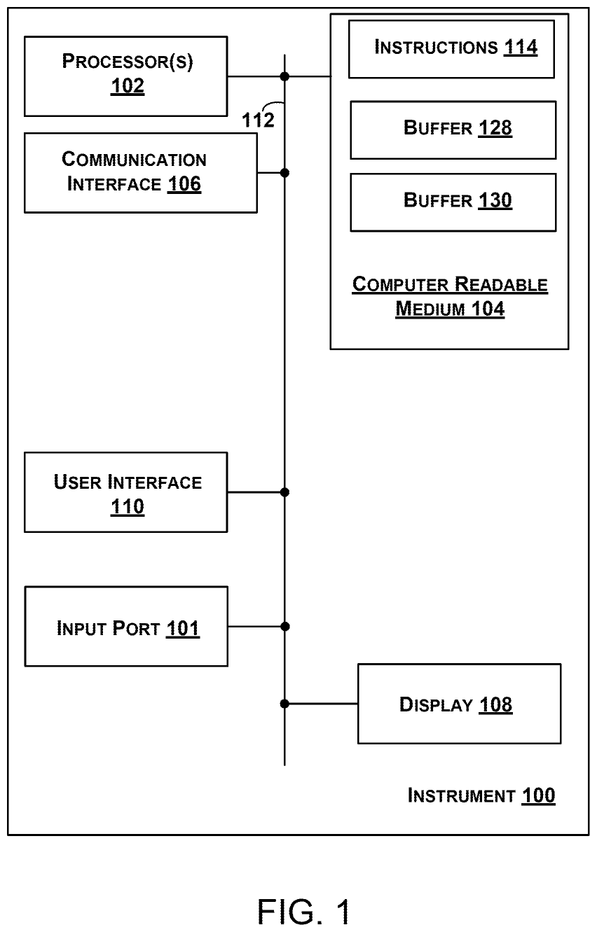

FIG. 1 is a block diagram of an instrument 100. The instrument 100 includes an input port 101, one or more processors 102, a non-transitory computer readable medium 104, a communication interface 106, a display 108, and a user interface 110. Components of the instrument 100 are linked together by a system bus, network, or other connection mechanism 112.

The input port 101 can include positive and negative test lead jacks or an oscilloscope test lead connector such as a pin tip jack, a banana jack, a binding post, a Bayonet Neill-Concelman (BNC) connector, or a subminiature version B (SMB) jack. The input port 101 could include or be configured to connect to a meter or oscilloscope test lead. The input port 101 generally includes one or more analog-to-digital controllers such that voltages detected at the input port 101 can be interpreted and processed by the instrument 100.

The one or more processors 102 can be any type of processor(s), such as a microprocessor, a digital signal processor, a multicore processor, etc., coupled to the non-transitory computer readable medium 104.

The non-transitory computer readable medium 104 can be any type of memory, such as volatile memory like random access memory (RAM), dynamic random access memory (DRAM), static random access memory (SRAM), or non-volatile memory like read-only memory (ROM), flash memory, magnetic or optical disks, or compact-disc read-only memory (CD-ROM), among other devices used to store data or programs on a temporary or permanent basis.

Additionally, the non-transitory computer readable medium 104 can be configured to store instructions 114. The instructions 114 are executable by the one or more processors 102 to cause the instrument 100 to perform any of the functions or methods described herein.

The non-transitory computer readable medium 104 also includes a buffer 128 and a buffer 130. The buffer 128 and the buffer 130 are designated memory spaces that typically take the form of a circular buffer. That is, the instrument 100 generally writes data to the buffer 128 and the buffer 130 until the buffer 128 and the buffer 130 are full, then continues to overwrite the oldest information within the buffer 128 and the buffer 130 with new information. Other operation modes are possible as well.

The communication interface 106 can include hardware to enable communication within the instrument 100 and/or between the instrument 100 and one or more other devices. The hardware can include transmitters, receivers, and antennas, for example. The communication interface 106 can be configured to facilitate communication with one or more other devices, in accordance with one or more wired or wireless communication protocols. For example, the communication interface 106 can be configured to facilitate wireless data communication for the instrument 100 according to one or more wireless communication standards, such as one or more Institute of Electrical and Electronics Engineers (IEEE) 801.11 standards, ZigBee standards, Bluetooth standards, etc. As another example, the communication interface 106 can be configured to facilitate wired data communication with one or more other devices.

The display 108 can be any type of display component configured to display data. As one example, the display 108 can include a touchscreen display. As another example, the display 108 can include a flat-panel display, such as a liquid-crystal display (LCD) or a light-emitting diode (LED) display. Additionally or alternatively, the display 108 includes a virtual reality display, an extended reality display, and/or an augmented reality display.

The user interface 110 can include one or more pieces of hardware used to provide data and control signals to the instrument 100. For instance, the user interface 110 can include a mouse or a pointing device, a keyboard or a keypad, a microphone, a touchpad, or a touchscreen, among other possible types of user input devices. Generally, the user interface 110 can enable an operator to interact with a graphical user interface (GUI) provided by the instrument 100 (e.g., displayed by the display 108).

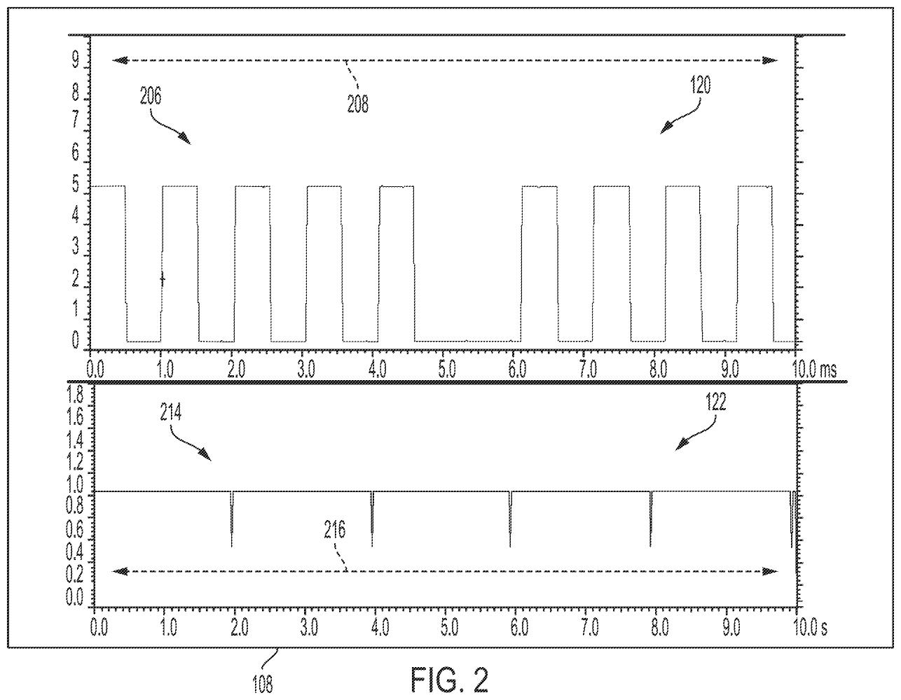

FIG. 2 shows the display 108 of the instrument 100. As shown, the instrument 100 generates and displays the first dataset 120 that indicates voltages (e.g., instantaneous voltages) of a signal detected at the input port 101 over a time period. In various examples, the voltages indicated by the first dataset 120 are a proxy for another metric such as a fuel injector duty cycle, a wheel speed, a mass air flow, a cam shaft position, or a cam shaft position frequency. In this example, the first dataset 120 represents a square wave periodically oscillating from approximately 0 volts to approximately 5 volts. For example, the first dataset 120 is a scatter plot of points within the display 108 that map discrete voltages respectively to discrete points in time. As shown, the instrument 100 displays a first part 206 of the first dataset 120 that corresponds to a portion 208 of the time period.

One of skill in the art will understand that that first dataset 120 could indirectly indicate instantaneous currents that correspond to the measured voltages.

In one example, the instrument 100 overwrites any data within the buffer 128 with the first dataset 120, when the buffer 128 is full. That is, the instrument 100 (e.g., continuously) overwrites older data representing the voltage detected at the input port 101 with newer data representing the voltage detected at the input port 101.

The instrument 100 also generates and displays (e.g., simultaneously with the first dataset 120) the second dataset 122 that indicates values of a derived characteristic of the signal over the time period. More specifically, the instrument 100 calculates sequential values of the characteristic of the signal over the time period. In this example, the second dataset 122 represents an oscillation frequency of the signal that is mostly steady at about 1 Hz but periodically exhibits an anomaly where the frequency quickly decreases to about 0.5 Hz and then quickly recovers to about 1 Hz. In other examples, the derived characteristic is a duty cycle of the signal, a pulse width of the signal, a period of the signal, an average value of the signal, a DC voltage of the signal, or a root mean square (RMS) value of the signal.

The second dataset 122 is a scatter plot of points within the display 108 that map discrete derived values respectively to discrete times. As shown, the instrument 100 displays a first part 214 of the second dataset 122 corresponding to a portion 216 of the time period. In other examples, the first dataset 120, the second dataset 122, and an additional dataset representing an additional derived characteristic of the signal can be simultaneously displayed within respective panels of the display 108. The displayed portions of the first dataset 120 and the second dataset 122 generally overlap in time to at least some degree. In FIG. 2, the portion 216 of the time period is longer than the portion 208 and completely includes the portion 208 of the time period, but other examples are possible.

In one example, the instrument 100 overwrites any data within the buffer 130 with the second dataset 122 (e.g., when the buffer 130 is full). That is, the instrument 100 (e.g., continuously) overwrites older data representing the derived characteristic of the voltage detected at the input port 101 with newer data representing the derived characteristic of the voltage detected at the input port 101.

Typically, the buffer 128 (e.g., a 127 MB buffer) is larger than the buffer 130 (e.g., a 1 MB buffer) and the instrument 100 writes the first dataset 120 to the buffer 128 at faster rate (e.g., kilo-samples per second or KSPS) than the instrument 100 writes the second dataset 122 to the buffer 130.

For example, the first buffer 128 can operate with a 1 millisecond (ms) sweep period, a 2.2 minute buffer depth, and a 500 ksps data retention rate. In another example, the first buffer 128 operates with a 2 ms sweep period, a 4.4 minute buffer depth, and a 250 ksps data retention rate. In another example, the first buffer 128 operates with a 5 ms sweep period, an 11 minute buffer depth, and a 1000 ksps data retention rate. In another example, the first buffer 128 operates with a 10 ms sweep period, a 22 minute buffer depth, and a 50 ksps data retention rate. In another example, the first buffer 128 operates with a 25 ms sweep period, a 55 minute buffer depth, and a 20 ksps data retention rate. In another example, the first buffer 128 operates with a 50 ms sweep period, a 110 minute buffer depth, and a 10 ksps data retention rate.

Similarly, the second buffer 130 can operate with a 1 second sweep duration and a 17 minute buffer depth. In another example, the second buffer 130 operates with a 2 second sweep duration and a 34 minute buffer depth. In another example, the second buffer 130 operates with a 5 second sweep duration and an 85 minute buffer depth.

In some examples, the instrument 100 receives a command via the user interface 110 and responsively causes the replacing of prior data (e.g., the first part 206 of the first dataset 120) within the display 108 and/or the buffer 128 to stop. Similarly, the instrument 100 can receive a command via the user interface 110 and responsively cause the replacing of prior data (e.g., the first part 214 of the second dataset 122) within the display 108 to stop. In some examples, a single command can cause the replacing of prior data within the display 108 and both buffers to stop. In other examples, separate commands can be used with respect to the first dataset 120 and the second dataset 122.

In some examples, the instrument 100 receives a selection of the part 206 of the first dataset 120 via the user interface 110 (e.g., while displaying a larger part of the first dataset 120) and responsively generates the second dataset 122 in response to receiving the selection. In this way, the instrument 100 can save computing resources by computing the derived characteristic only when needed.

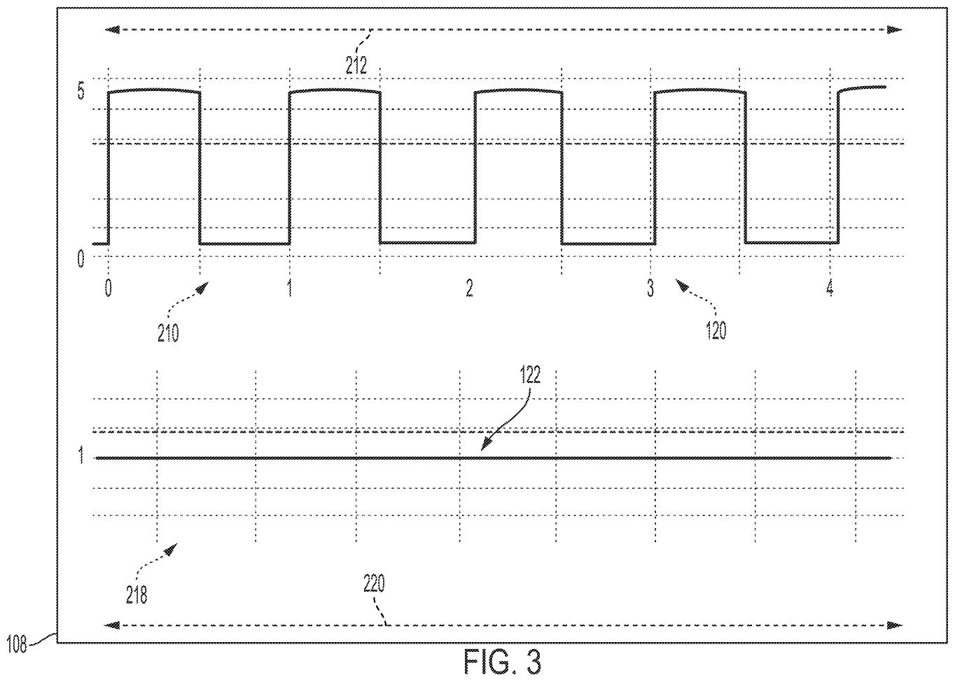

FIG. 3 again shows the display 108 of the instrument 100. As shown, the instrument 100 replaces the first part 206 of the first dataset 120 within the display 108 with a second part 210 of the first dataset 120 corresponding to a portion 212 of the time period that follows the portion 208 of the time period. In this example, the first dataset 120 represents a square wave periodically oscillating from approximately 0 volts to approximately 5 volts.

As shown, the anomaly in the oscillation frequency of the signal is not present in the second part 210 of the first dataset 120. That is, the oscillation frequency of the signal remains static at 1 Hz. The instrument 100 replaces the first part 214 of the second dataset 122 within the display 108 with a second part 218 of the second dataset 122 that corresponds to a portion 220 of the time period that follows the portion 216 of the time period.

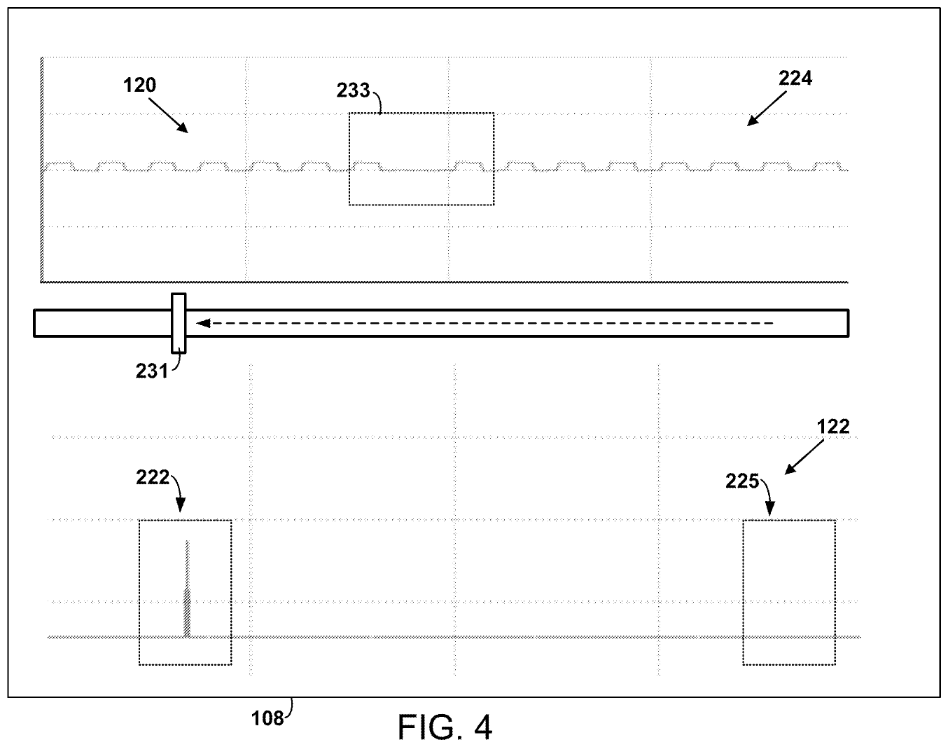

FIG. 4 again shows the display 108 of the instrument 100. As shown, the user interface 110 of the instrument receives a selection of a portion 222 of the second dataset 122. For example, the user interface 110 receives a leftward touch and drag input that causes a cursor 231 to move leftward (e.g., backward in time) across the display 108 to align with the portion 222 of the second dataset 122. In another example, the user interface 110 could receive a simple touch input adjacent to the portion 222.

In response to receiving the selection, the instrument 100 updates the display 108 to display a portion 224 of the first dataset 120 that corresponds in time to the portion 222 of the second dataset 122. In this example, the upper panel of the display 108 shows a much shorter time period than the bottom panel of the display 108 and is refreshed much more often. For example, a user might notice that the second dataset 122 exhibits an anomaly (e.g., a pulse width sharply increases then sharply decreases) at the portion 222 and operate the instrument 100 to display the portion 224 of the first dataset 120 (e.g., the voltage signal itself) that corresponds to the portion 222 of the second dataset 122. As shown, the portion 224 of the first dataset 120 exhibits an anomaly 233 in pulse width that shows in a different form in the second dataset 122 within the portion 222. Prior to receiving the selection, the instrument 100 displays a non-anomalous portion of the first dataset 120 that corresponds to a portion 225 of the second dataset 122 (e.g., a portion that does not exhibit an anomaly). In the example of FIG. 4, the selection does not cause a change in the display of the second dataset 122.

In various examples, each pixel of the displayed portion of the second dataset 122 is assigned a unique Waveform ID (WID). For example, if the display is 500 pixels wide from left to right, each pixel (e.g., each increment of WID) will represent 1/500 of the displayed portion of the second dataset 122. By further example, if the displayed portion of the second dataset 122 is 1 second of data, each pixel will represent 2 ms. When a pixel of the second dataset 122 is selected as a reference for zoomed display of the first dataset 120, the corresponding WID for the selected pixel is used to retrieve the underlying data from the first buffer 128. The data retrieved from the first buffer 128 will generally be chronologically centered with respect to the selected pixel of the second dataset 122, but other examples are possible.

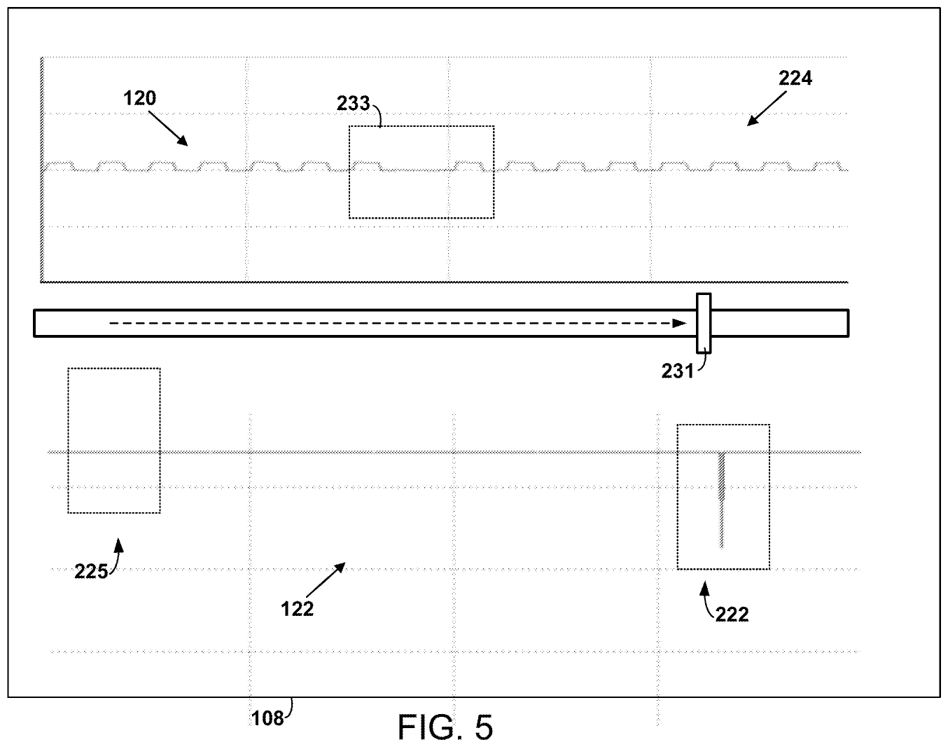

FIG. 5 again shows the display 108 of the instrument 100. As shown, the user interface 110 of the instrument receives a selection of a portion 222 of the second dataset 122. For example, the user interface 110 receives a rightward touch and drag input that causes a cursor 231 to move rightward (e.g., forward in time) across the display 108 to align with the portion 222 of the second dataset 122. In another example, the user interface 110 could receive a simple touch input adjacent to the portion 222.

In response to receiving the selection, the instrument 100 updates the display 108 to display a portion 224 of the first dataset 120 that corresponds in time to the portion 222 of the second dataset 122. In this example, the upper panel of the display 108 shows a much shorter time period than the bottom panel of the display 108 and is refreshed much more often. For example, a user might notice that the second dataset 122 exhibits an anomaly (e.g., a duty cycle sharply decreases then sharply increases) at the portion 222 and operate the instrument 100 to display the portion 224 of the first dataset 120 (e.g., the voltage signal itself) that corresponds to the portion 222 of the second dataset 122. As shown, the portion 224 of the first dataset 120 exhibits an anomaly 233 in duty cycle that shows in a different form in the second dataset 122 within the portion 222. Prior to receiving the selection, the instrument 100 displays a non-anomalous portion of the first dataset 120 that corresponds to a portion 225 of the second dataset 122 (e.g., a portion that does not exhibit an anomaly). In the example of FIG. 5, the selection does not cause a change in the display of the second dataset 122.

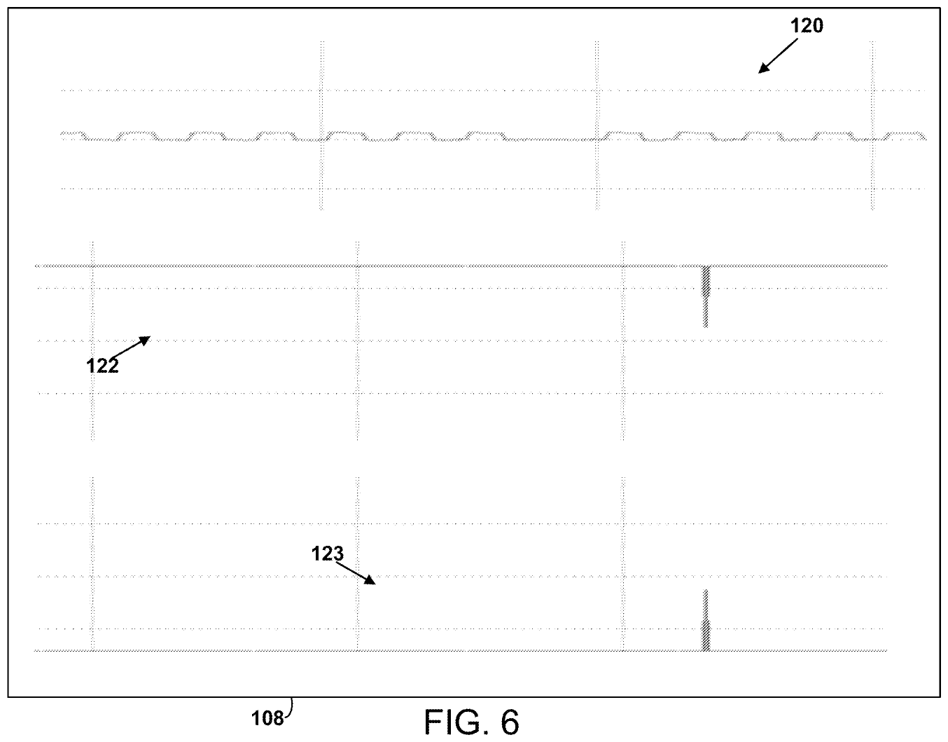

FIG. 6 again shows the display 108 of the instrument 100. In addition to generating and displaying the first dataset 120 and the second dataset 122, the instrument 100 also generates and displays a third dataset 123 indicating second values of a second derived characteristic of the signal over the time period. In this example, the second dataset 122 represents a duty cycle of the signal and the third dataset 123 represents a pulse width of the signal. As shown, the third dataset 123 is displayed simultaneously with the first dataset 120 and the second dataset 122.

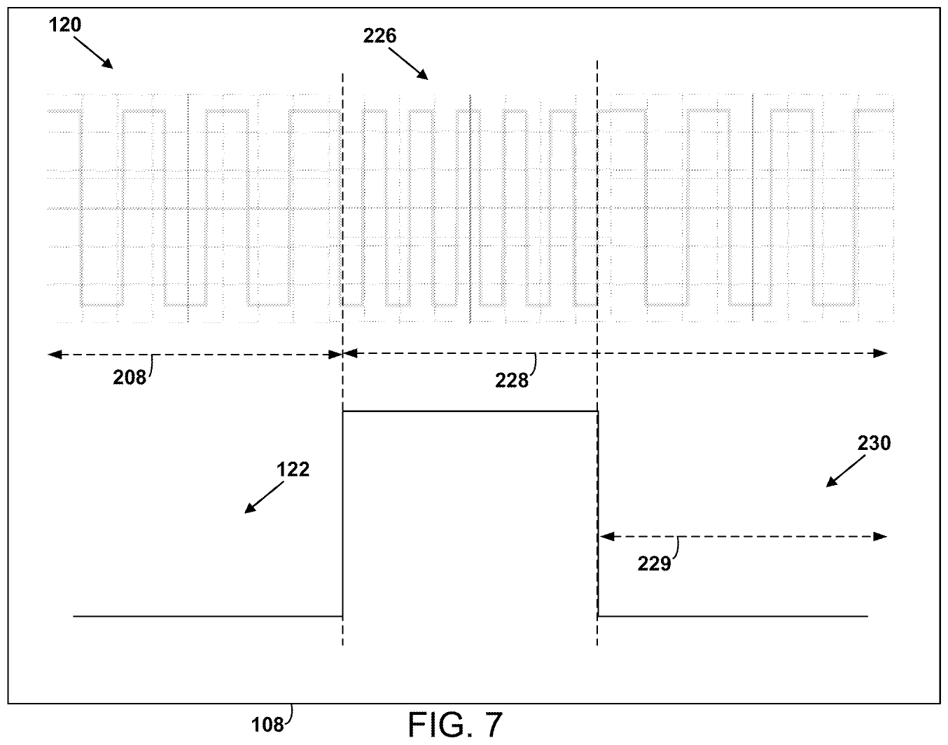

FIG. 7 again shows the display 108 of the instrument 100. As described above, the instrument 100 generates the first dataset 120 indicating voltages of the signal detected at the input port 101 over the portion 208 of the time period, displays the first dataset 120 graphically on the display 108, generates a second dataset 122 indicating values of a derived characteristic of the signal over the portion 208 of the time period, and displays the second dataset 122 graphically on the display 108. In this example, the upper panel of the display 108 and the lower panel of the display 108 show the same time periods and the derived characteristic is the oscillation frequency of the signal.

Next, the instrument generates a third dataset 226 indicating voltages of the signal detected at the input port 101 over a portion 228 of the time period that follows the portion 208 of the time period and generates a fourth dataset 230 indicating values of the derived characteristic of the signal over the portion 228 of the time period. As shown, the signal increases in frequency beginning at the transition from the portion 208 of the time period to the portion 228 of the time period and then resumes the original frequency at the transition to the portion 229 of the time period.

The instrument 100 then stores the third dataset 226 and/or the fourth dataset 230 in response to determining that the fourth dataset 230 satisfies a criterion. For example, the instrument 100 can automatically store the third dataset 226 and/or the fourth dataset 230 in response to determining that values of the derived characteristic indicated by the fourth dataset 230 are greater than any values of the derived characteristic indicated by any of the second dataset 122. The display of the third dataset 226 could occur automatically or in response to a request to display data that satisfies the criterion, received via the user interface 110. The instrument 100 could overwrite the first dataset 120 with the third dataset 226 within the buffer 128 or the instrument 100 could store the third dataset 226 in another location. Similarly, the instrument 100 could overwrite the second dataset 122 with the fourth dataset 230 within the buffer 130 or the instrument 100 could store the fourth dataset 230 in another location.

In another example that is not shown, the instrument 100 can automatically store the third dataset 226 and/or the fourth dataset 230 in response to determining that values of the derived characteristic indicated by the fourth dataset 230 are less than any values of the derived characteristic indicated by any of the second dataset 122.

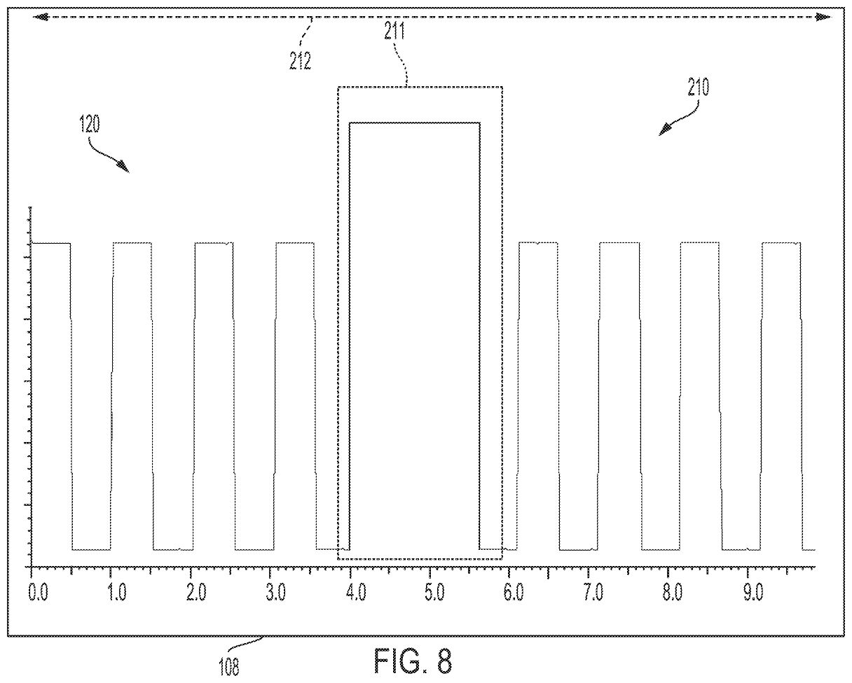

FIG. 8 again shows the display 108 of the instrument 100. After generating and displaying the first part 206 of the first dataset 120 that corresponds to the portion 208 of the time period and generating and displaying the first part 214 of the second dataset 122 that corresponds to the portion 216 of the time period (see FIG. 2), the instrument 100 generates and displays the second part 210 of the first dataset 120 corresponding to the portion 212 of the time period that follows the portion 208 of the time period.

In an example, the instrument 100 stores the second part 210 of the first dataset 120 in response to determining that the second part 210 of the first dataset 120 satisfies a criterion. For example, the criterion could be that the second part 210 of the first dataset 120 includes data 211 corresponding to instantaneous voltages that exceed any instantaneous voltages corresponding to any of the other portions of the first dataset 120. In various examples, the second part 210 could be stored automatically or the second part 210 could be stored in response to a request received via the user interface 110 to display and/or store data that satisfies the criterion. In some examples, the instrument 100 overwrites the first part 206 of the first dataset 120 within the buffer 128, but in other examples the second part 210 is stored in another location. In another example, the criterion could be that the second part 210 of the first dataset 120 includes the data 211 corresponding to instantaneous voltages having absolute values that exceed absolute values of any instantaneous voltages corresponding to any other portion of the first dataset 120.

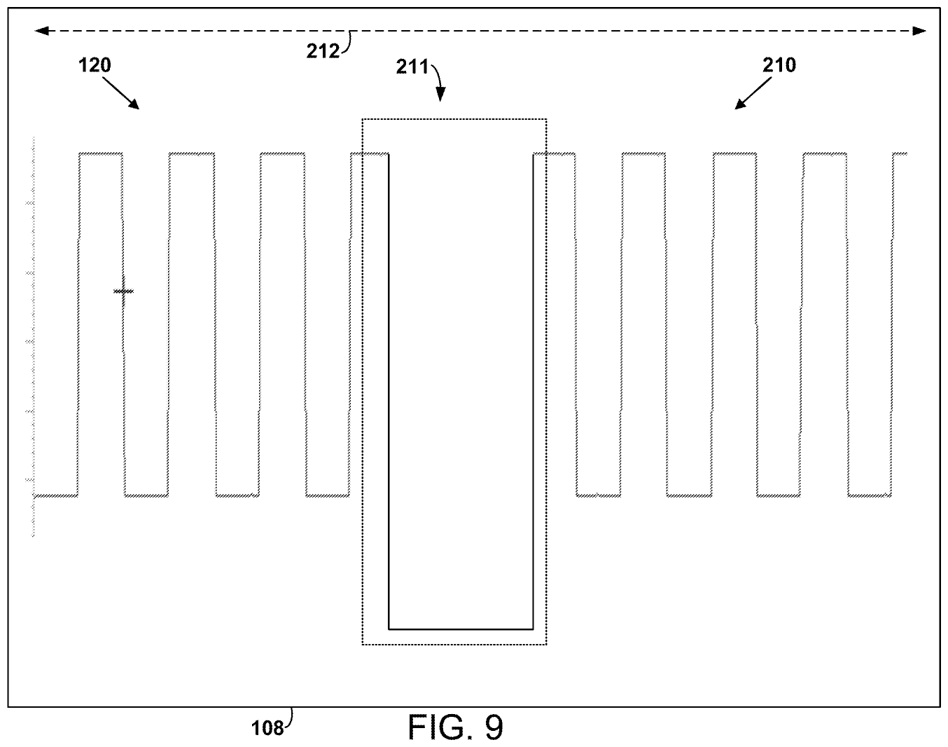

FIG. 9 again shows the display 108 of the instrument 100. After generating and displaying the first part 206 of the first dataset 120 that corresponds to the portion 208 of the time period and generating and displaying the first part 214 of the second dataset 122 that corresponds to the portion 216 of the time period (see FIG. 2), the instrument 100 generates and displays the second part 210 of the first dataset 120 corresponding to the portion 212 of the time period that follows the portion 208 of the time period.

In an example, the instrument 100 stores the second part 210 of the first dataset 120 in response to determining that the second part 210 of the first dataset 120 satisfies a criterion. For example, the criterion could be that the second part 210 of the first dataset 120 includes data 211 corresponding to instantaneous voltages that are less than any instantaneous voltages corresponding to any of the other portions of the first dataset 120. In various examples, the second part 210 could be stored automatically or the second part 210 could be stored in response to a request received via the user interface 110 to display and/or store data that satisfies the criterion. In some examples, the instrument 100 overwrites the first part 206 of the first dataset 120 within the buffer 128, but in other examples the second part 210 is stored in another location.

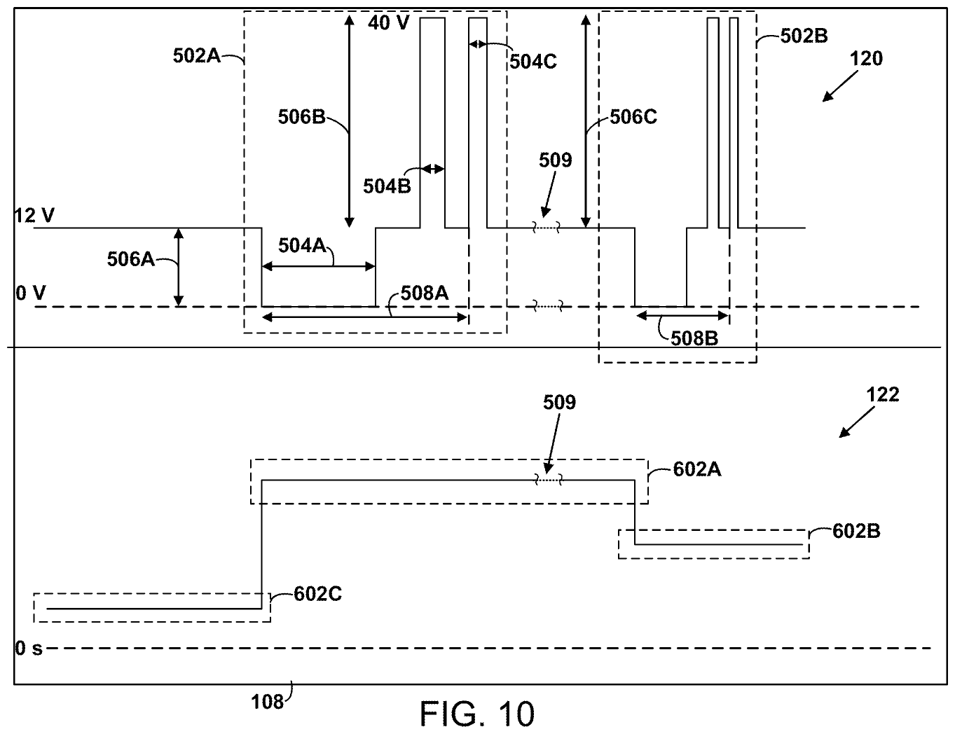

FIG. 10 again shows the display 108 of the instrument 100. In FIG. 10, the display 108 displays the first dataset 120 in the upper panel and the second dataset 122 in the lower panel. In some examples, the instrument 100 identifies a portion of the signal detected at the input port 101 that satisfies a criterion (e.g. the instrument 100 identifies a portion 502A of the first dataset 120 that satisfies the criterion). For example, the instrument 100 identifies the portion 502A that satisfies the criterion of qualifying as a valid fuel injector pulse that is configured to cause an automobile fuel injector to operate. In some examples, it can be useful to isolate such a portion of a signal for display and inspection.

For example, the instrument 100 can identify the portion 502A in the following manner. The instrument 100 determines that the portion 502A includes a section 504A that represents a deviation 506A from a baseline voltage (e.g., 12 volts) of at least a first threshold voltage (e.g., −10 volts+/−10%), followed by a section 504B that represents a deviation 506B from the baseline voltage of at least a second threshold voltage (e.g., 26 volts+/−10%), followed by a section 504C that represents a deviation 506C from the baseline voltage of at least the second threshold voltage (e.g., 26 volts+/−10%). As shown, the deviation 506A of the section 504A has a polarity that is opposite the deviation 506B and the deviation 506C of the section 504B and the section 504C.

In this example, the section 504A has a duration of a few milliseconds whereas the section 504B and the section 504C each have a duration of less than one millisecond. At 509, FIG. 10 indicates that the elapsed time between the portion 502A and the portion 502B is greater than actually shown, for purposes of clarity.

To determine that the portion 502A satisfies the criterion, the instrument 100 can further determine that the section 504A, the section 504B, and the section 504C collectively correspond to a duration that is less than a threshold duration (e.g., 10 ms+/−10%).

To determine that the portion 502A satisfies the criterion, the instrument 100 can further determine that the section 504A, the section 504B, and the section 504C each have a duration that is greater than a threshold duration (e.g., 100 μs+/−10%)).

Next, the instrument 100 determines a pulse width 508A of the portion 502A and determines a pulse width 508B of a portion 502B of the first dataset 120. In this context, the instrument 100 displays the second dataset 122 such that a portion 602A of the second dataset 122 indicates the pulse width 508A of the portion 502A and such that a portion 602B of the second dataset 122 indicates the pulse width 508B of the portion 502B (e.g., via the vertical axis of the lower panel). The section 602C indicates a pulse width of a portion of the first dataset 120 that precedes the portion 502A and is not shown.

As shown in FIG. 10, the pulse width 508A begins at a leading edge of the section 504A and ends at a leading edge of the section 504C. The pulse width 508B is defined similarly with respect to the portion 502B.

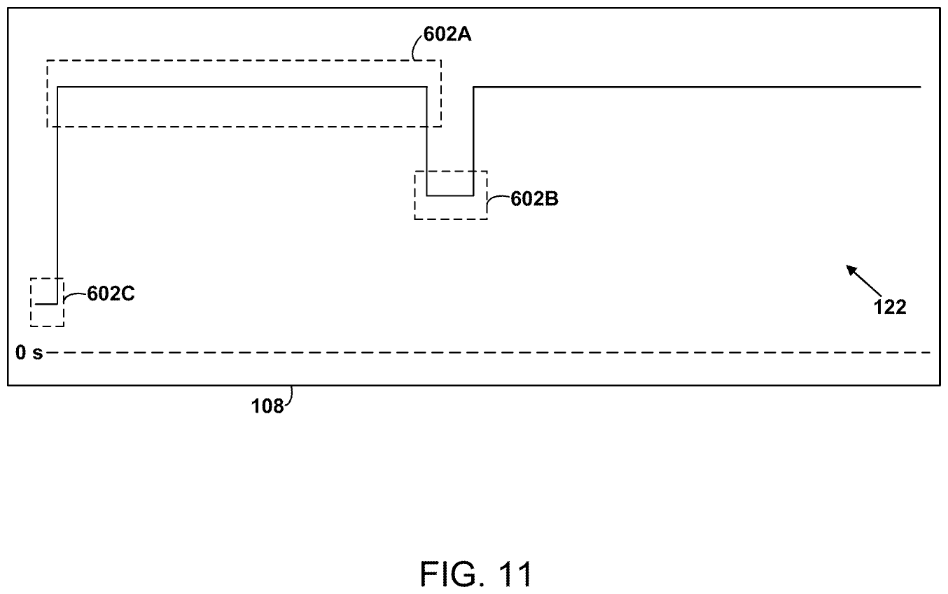

FIG. 11 shows only the lower panel of the display 108 of the instrument 100. In this example, the time scale on the horizontal axis is expanded when compared to the lower panel of the display 108 shown in FIG. 10. Thus, FIG. 11 might show more representative proportionality of the time that elapses corresponding to various pulse widths when compared to FIG. 10.

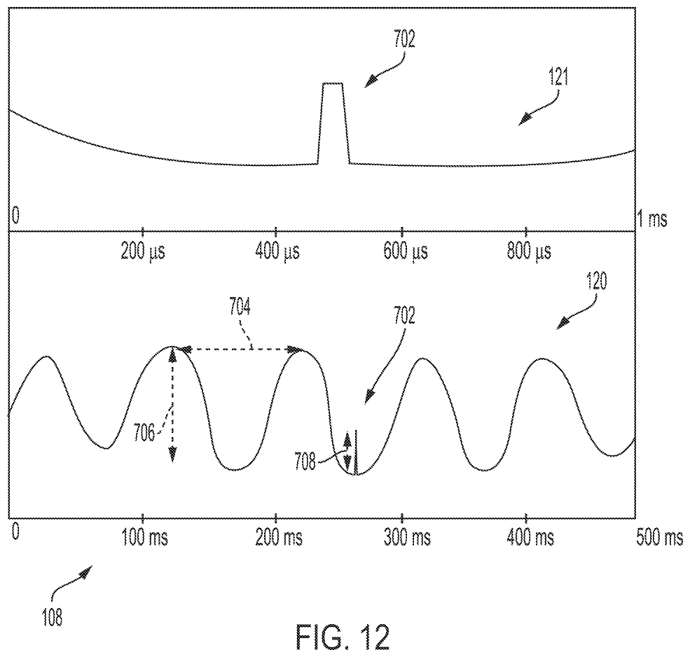

FIG. 12 again shows the display 108 of the instrument 100. As shown, the instrument 100 generates the dataset 120 indicating voltages of a signal detected at the input port 101. The instrument 100 displays the dataset 120 graphically within a lower panel of the display 108 with a first time resolution (e.g., the full width of the lower panel corresponds to 500 ms).

The instrument 100 also determines that an anomaly 702 exists within the dataset 120. This can involve the instrument 100 determining a period 704 and an amplitude 706 of the signal, determining that the signal exhibits a voltage deviation 708 that exceeds a threshold percentage (e.g., 10% or 9-11%) of the amplitude 706, and determining that the voltage deviation 708 occurs within a time period that is less than a threshold percentage (e.g., 3% or 2-4%) of the period 704. The instrument 100 also displays, with a second time resolution (e.g., the full width of the upper panel corresponds to 1 ms) that is greater than the first time resolution, a subset 121 of the dataset 120 that includes the anomaly 702 within the upper panel of the display 108.

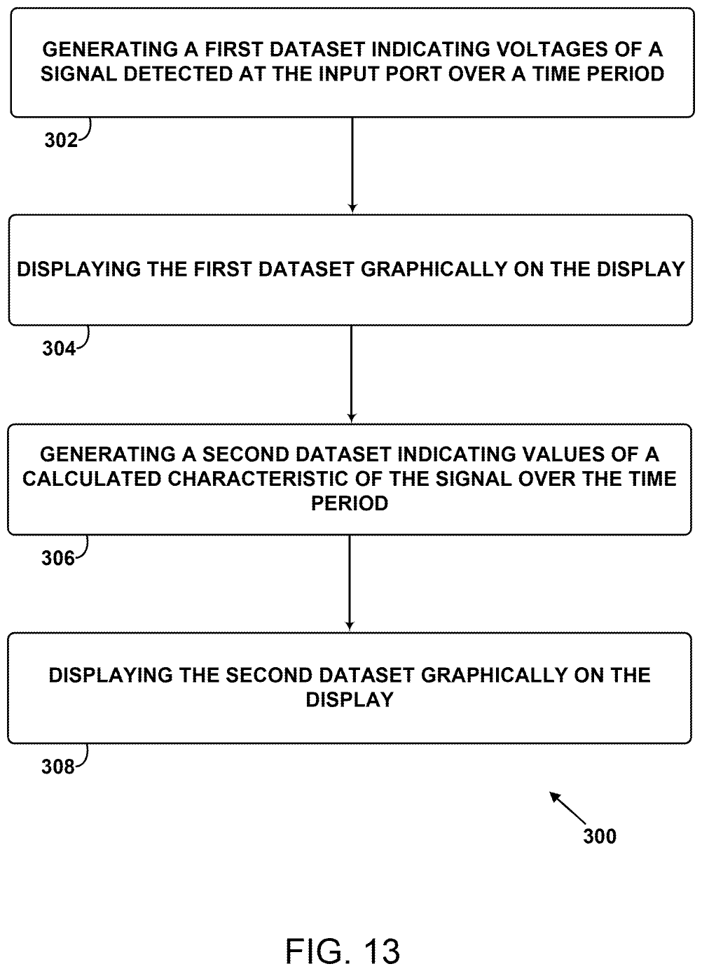

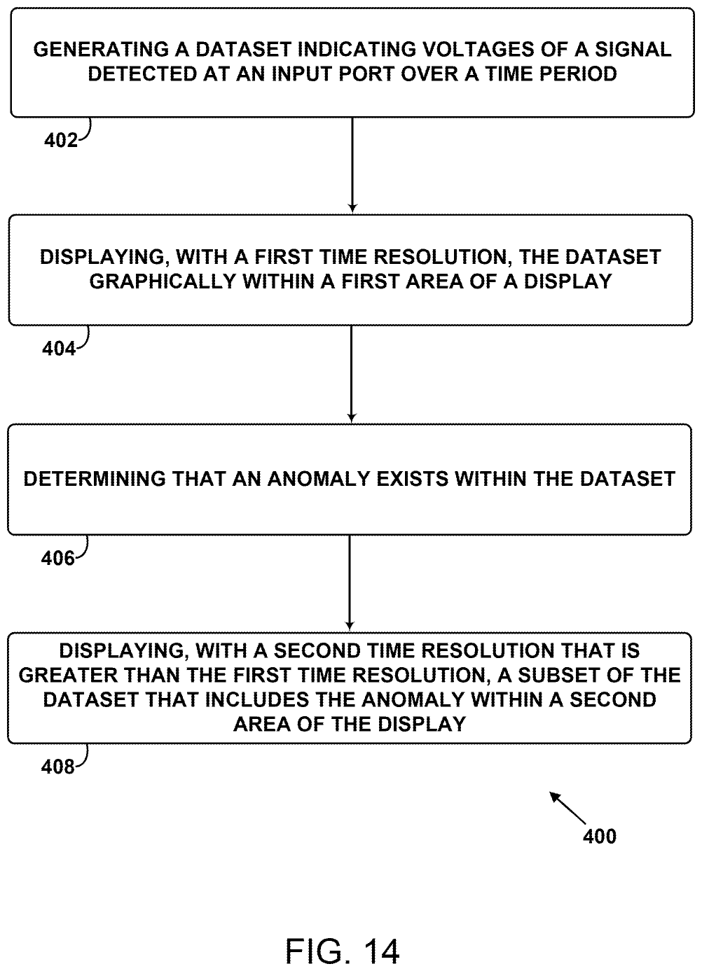

FIG. 13 and FIG. 14 are block diagrams of a method 300 and a method 400 that can be performed by the instrument 100. As shown in FIG. 13 and FIG. 14, the method 300 and the method 400 include one or more operations, functions, or actions as illustrated by blocks 302, 304, 306, 308, 402, 404, 406, and 408. Although the blocks are illustrated in a sequential order, these blocks may also be performed in parallel, and/or in a different order than those described herein. Also, the various blocks may be combined into fewer blocks, divided into additional blocks, and/or removed based upon the desired implementation.

Details regarding the blocks 302, 304, 306, 308, 402, 404, 406, and 408 are found above with reference to FIGS. 2-12.

At block 302, the method 300 includes generating the first dataset 120 indicating voltages of a signal detected at an input port 101 over a time period.

At block 304, the method 300 includes displaying the first dataset 120 graphically on the display 108.

At block 306, the method 300 includes generating the second dataset 122 indicating values of the derived characteristic of the signal over the time period.

At block 308, the method 300 includes displaying the second dataset 122 graphically on the display 108.

At block 402, the method 400 includes generating the dataset 120 indicating voltages of a signal detected at the input port 101.

At block 404, the method 400 includes displaying, with a first time resolution, the dataset 120 graphically within a first area of the display 108.

At block 406, the method 400 includes determining that the anomaly 702 exists within the dataset 120.

At block 408, the method 400 includes displaying, with a second time resolution that is greater than the first time resolution, a subset 121 of the dataset 120 that includes the anomaly 702 within a second area of the display 108.

Example embodiments have been described above. Those skilled in the art will understand that changes and modifications can be made to the described embodiments without departing from the true scope of the present invention, which is defined by the claims.

Additional embodiments, based on the features or functions described herein, can be embodied as a computer-readable medium storing program instructions, that when executed by a processor cause a set of functions to be performed, the set of functions comprising the features or functions of the aspects and embodiments described herein.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims, along with the full scope of equivalents to which such claims are entitled. It is also to be understood that the terminology used herein is for the purpose of describing particular embodiments only, and is not intended to be limiting.

Embodiments of the present disclosure may thus relate to one of the enumerated example embodiments (EEEs) listed below.

EEE 1 is a method comprising: generating a first dataset indicating voltages of a signal detected at an input port over a time period; displaying the first dataset graphically on a display; generating a second dataset indicating values of a derived characteristic of the signal over the time period; and displaying the second dataset graphically on the display.

EEE 2 is the method of EEE 1, wherein displaying the first dataset comprises: displaying a first part of the first dataset corresponding to a first portion of the time period; and replacing the first part within the display with a second part of the first dataset corresponding to a second portion of the time period that follows the first portion.

EEE 3 is the method of EEE 2, further comprising: receiving a command via a user interface; and causing the replacing the first part within the display to stop.

EEE 4 is the method of any one of EEEs 1-3, wherein displaying the second dataset comprises: displaying a first part of the second dataset corresponding to a first portion of the time period; and replacing the first part within the display with a second part of the second dataset corresponding to a second portion of the time period that follows the first portion.

EEE 5 is the method of EEE 4, further comprising receiving a command via a user interface; and causing the replacing the first part within the display to stop.

EEE 6 is the method of any one of EEEs 1-5, further comprising receiving, via a user interface, a selection of a part of the first dataset, wherein generating the second dataset comprises generating the second dataset in response to receiving the selection

EEE 7 is the method of any one of EEEs 1-6, further comprising: receiving, via a user interface, a selection of a first portion of the second dataset; and displaying a second portion of the first dataset on the display in response to receiving the selection, wherein the second portion of the first dataset and the first portion of the second dataset correspond to a common portion of the time period.

EEE 8 is the method of EEE 7, wherein receiving the selection comprises receiving a command to move a cursor within the display such that the cursor is aligned with the first portion of the second dataset.

EEE 9 is the method of EEE 7 or EEE 8, wherein receiving the selection comprises receiving a touchscreen gesture at a position within the display at which the first portion of the second dataset is displayed.

EEE 10 is the method of any one of EEEs 1-9, wherein the voltages are instantaneous voltages of the signal.

EEE 11 is the method of any one of EEEs 1-13, wherein displaying the second dataset comprises displaying the second dataset simultaneously with displaying the first dataset.

EEE 12 is the method of any one of EEEs 1-11, wherein the derived characteristic is a duty cycle of the signal, a pulse width of the signal, a period of the signal, an average value of the signal, a DC voltage of the signal, a root mean square (RMS) value of the signal, or a frequency of the signal.

EEE 13 is the method of any one of EEEs 1-12, further comprising: identifying a first portion of the signal that satisfies a criterion; and determining a pulse width of the first portion, wherein displaying the second dataset comprises displaying the second dataset such that a second portion of the second dataset indicates a pulse width of the first portion.

EEE 14 is the method of EEE 13, wherein identifying the first portion comprises determining that the first portion of the signal includes: a first section that represents a first deviation from a baseline voltage of at least a first threshold voltage, followed by a second section that represents a second deviation from the baseline voltage of at least a second threshold voltage, wherein the second threshold voltage is greater than the first threshold voltage and the second deviation has a polarity that is opposite the first deviation, followed by a third section that represents a third deviation from the baseline voltage of at least the second threshold voltage, wherein the third deviation has a polarity that is opposite the first deviation.

EEE 15 is the method of EEE 14, wherein identifying the first portion further comprises determining that the first section, the second section, and the third section collectively correspond to a duration that is less than a threshold duration.

EEE 16 is the method of EEE 14 or EEE 15, wherein the pulse width begins at a leading edge of the first section and ends at a leading edge of the third section.

EEE 17 is the method of any one of EEEs 14-16, wherein identifying the first portion further comprises determining that the first section, the second section, and the third section each have a duration that is greater than a threshold duration.

EEE 18 is the method of any one of EEEs 1-17, further comprising: generating a third dataset indicating second values of a second derived characteristic of the signal over the time period; and displaying the third dataset graphically on the display.

EEE 19 is the method of EEE 18, wherein displaying the third dataset comprises displaying the third dataset simultaneously with displaying the first dataset.

EEE 20 is a method comprising: generating a dataset indicating voltages of a signal detected at an input port; displaying, with a first time resolution, the dataset graphically within a first area of a display; determining that an anomaly exists within the dataset; and displaying, with a second time resolution that is greater than the first time resolution, a subset of the dataset that includes the anomaly within a second area of the display.

EEE 21 is the method of EEE 20, wherein determining that the anomaly exists within the dataset comprises: determining a period and an amplitude of the signal; determining that the signal exhibits a voltage deviation that exceeds a threshold percentage of the amplitude; and determining that the voltage deviation occurs within a time period that is less than a threshold percentage of the period.

EEE 22 is a computing system comprising: a computer-readable medium; at least one processor; and program instructions stored on the computer-readable medium and executable by the at least one processor to carry out operations, the operations comprising a method in accordance with any one of EEEs 1 to 21.

EEE 23 is a computer-readable medium having stored thereon instructions executable by at least one processor to cause a computing system to perform operations, the operations comprising a method in accordance with any one of EEEs 1 to 21.

While various example aspects and example embodiments have been disclosed herein, other aspects and embodiments will be apparent to those skilled in the art. The various example aspects and example embodiments disclosed herein are for purposes of illustration and are not intended to be limiting, with the true scope and spirit being indicated by the following claims.

What is claimed is:

1. An instrument comprising:
an input port;
a display;
one or more processors; and
a computer readable medium storing instructions that, when executed by the one or more processors, cause the instrument to perform functions comprising:
generating a first dataset indicating voltages of a signal detected at the input port over a time period;
displaying the first dataset graphically on the display;
generating a second dataset indicating values of a derived characteristic of the signal over the time period; and
displaying the second dataset graphically on the display.

2. The instrument of claim 1, wherein displaying the first dataset comprises:
displaying a first part of the first dataset corresponding to a first portion of the time period; and
replacing the first part within the display with a second part of the first dataset corresponding to a second portion of the time period that follows the first portion.

3. The instrument of claim 2, further comprising a user interface, the functions further comprising:
receiving a command via the user interface; and
causing the replacing the first part within the display to stop in response to receiving the command.

4. The instrument of claim 1, wherein displaying the second dataset comprises:
displaying a first part of the second dataset corresponding to a first portion of the time period; and
replacing the first part within the display with a second part of the second dataset corresponding to a second portion of the time period that follows the first portion.

5. The instrument of claim 4, further comprising a user interface, the functions further comprising:
receiving a command via the user interface; and
causing the replacing the first part within the display to stop in response to receiving the command.

6. The instrument of claim 1, further comprising a user interface, the functions further comprising:
receiving, via the user interface, a selection of a part of the first dataset,
wherein generating the second dataset comprises generating the second dataset in response to receiving the selection.

7. The instrument of claim 1, further comprising a user interface, the functions further comprising:
receiving, via the user interface, a selection of a first portion of the second dataset; and
displaying a second portion of the first dataset on the display in response to receiving the selection, wherein the second portion of the first dataset and the first portion of the second dataset correspond to a common portion of the time period.

8. The instrument of claim 7, wherein receiving the selection comprises receiving a command to move a cursor within the display such that the cursor is aligned with the first portion of the second dataset.

9. The instrument of claim 7, wherein receiving the selection comprises receiving a touchscreen gesture at a position within the display at which the first portion of the second dataset is displayed.

10. The instrument of claim 1, wherein the voltages are instantaneous voltages of the signal.

11. The instrument of claim 1, wherein displaying the second dataset comprises displaying the second dataset simultaneously with displaying the first dataset.

12. The instrument of claim 1, wherein the derived characteristic is a duty cycle of the signal, a pulse width of the signal, a period of the signal, an average value of the signal, a DC voltage of the signal, a root mean square (RMS) value of the signal, or a frequency of the signal.

13. The instrument of claim 1, the functions further comprising:
identifying a first portion of the signal that satisfies a criterion; and
determining a pulse width of the first portion,
wherein displaying the second dataset comprises displaying the second dataset such that a second portion of the second dataset indicates a pulse width of the first portion.

14. The instrument of claim 13, wherein identifying the first portion comprises determining that the first portion of the signal includes:
a first section that represents a first deviation from a baseline voltage of at least a first threshold voltage, followed by
a second section that represents a second deviation from the baseline voltage of at least a second threshold voltage, wherein the second threshold voltage is greater than the first threshold voltage and the second deviation has a polarity that is opposite the first deviation, followed by
a third section that represents a third deviation from the baseline voltage of at least the second threshold voltage, wherein the third deviation has a polarity that is opposite the first deviation.

15. The instrument of claim 14, wherein identifying the first portion further comprises determining that the first section, the second section, and the third section collectively correspond to a duration that is less than a threshold duration.

16. The instrument of claim 14, wherein the pulse width begins at a leading edge of the first section and ends at a leading edge of the third section.

17. The instrument of claim 14, wherein identifying the first portion further comprises determining that the first section, the second section, and the third section each have a duration that is greater than a threshold duration.

18. The instrument of claim 1, further comprising the functions further comprising:
generating a third dataset indicating second values of a second derived characteristic of the signal over the time period; and
displaying the third dataset graphically on the display.

19. The instrument of claim 18, wherein displaying the third dataset comprises displaying the third dataset simultaneously with displaying the first dataset.

20. A method comprising:
generating a first dataset indicating voltages of a signal detected at an input port over a time period;
displaying the first dataset graphically on a display;
generating a second dataset indicating values of a derived characteristic of the signal over the time period; and
displaying the second dataset graphically on the display.

21. A method comprising:
generating a dataset indicating voltages of a signal detected at an input port;
displaying, with a first time resolution, the dataset graphically within a first area of a display;
determining that an anomaly exists within the dataset; and
displaying, with a second time resolution that is greater than the first time resolution, a subset of the dataset that includes the anomaly within a second area of the display.

22. The method of claim 21, wherein determining that the anomaly exists within the first dataset comprises:
determining a period and an amplitude of the signal;
determining that the signal exhibits a voltage deviation that exceeds a threshold percentage of the amplitude; and
determining that the voltage deviation occurs within a time period that is less than a threshold percentage of the period.
